(19) United States
(12) Patent Application Publication
(10) Pub. No.: US 2007/0137699 A1
(43) Pub. Date: Jun. 21, 2007

(54) Solar cell and method for fabricating solar cell

(75) Inventors: Venkatesan Manivannan, Rexford, NY (US); James Neil Johnson, Schenectady, NY (US)

Correspondence Address: JOHN S. BEULICK (12764), ARMSTRONG TEASDALE LLP, ONE METROPOLITAN SQUARE, SUITE 2600, ST. LOUIS, MO, 63102-2740, US

(73) Assignee: General Electric Company

(21) Appl. No.: 11/303,831

(22) Filed: Dec. 16, 2005

(51) Int. Cl. H01L 31/00

(52) U.S. Cl. 136/261

(57) ABSTRACT

A method for fabricating a solar cell is provided. The method includes positioning a silicon substrate having a front surface and an opposing back surface in a plasma reaction chamber. A high-efficiency emitter structure is formed on the first surface of the silicon substrate. A back surface passivated structure is formed on the second surface of the silicon substrate.

### BACKGROUND OF THE INVENTION

This invention relates generally to solar cells and, more particularly, to a method for fabricating a solar cell.

Thermal oxides having a thickness greater than about 100 nm are commonly used for the production of high-efficiency silicon (Si) solar cells from monocrystalline and multicrystalline silicon. These conventional solar cells produce relatively high power conversion efficiencies due to the good surface passivation achieved by the reduction in density of interface states. However, there are distinct disadvantages with the process for fabricating these solar cells. First, the process is performed at high temperatures for a long period of time, thereby increasing a thermal budget required to fabricate these solar cells. Second, oxidation in a tube furnace takes place on each of a front side and a backside of the wafer, and good anti-reflection properties require the removal of oxide from the front side.

To overcome the difficulties associated with using a silicon dioxide (SiO₂) passivation layer, a silicon nitride (SiNₓ) layer can be deposited on the SiO₂ layer to improve the optical and electrical properties. However, SiNₓ layers are characterized by a loss in short-circuit current density (J_{sc}) due to the short circuiting of the inversion layers induced by the fixed charges in SiNₓ at rear contact points. As a result, a floating junction is shunted by the rear contact points and the passivation is reduced under operating conditions. Therefore, a back surface passivated (BSP) structure is needed that overcomes the disadvantages associated with the use of individual SiO₂ and SiNₓ materials.

Conventional structures for solar cells include an aluminum back surface field (Al BSF) formed by firing a screen-printed Al paste. Although this process is suited in terms of industrial feasibility, processing difficulties occur when an efficiency of the solar cell is higher than 18% and/or a wafer thickness is below 150 μm. This is due to the relatively poor electrical and optical properties of an Al BSF, which will reduce the cell performance on thin substrates. Further, the wafer bows during the Al firing process and, thus, produces a nonuniform BSF that results in unacceptably high back surface recombination velocity values.

### BRIEF DESCRIPTION OF THE INVENTION

In one aspect, the present invention provides a method for fabricating a solar cell. The method includes positioning a silicon substrate having a front surface and an opposing back surface in a plasma reaction chamber. A high-efficiency emitter structure is formed on the first surface of the silicon substrate. A back surface passivated structure is formed on the second surface of the silicon substrate.

In another aspect, the present invention provides a method for fabricating a solar cell using plasma deposition processes. The method includes positioning a silicon substrate in a plasma reaction chamber. The silicon substrate is heated to a temperature of about 120° C. to about 240° C. A plasma discharge is generated within the plasma reaction chamber to dissociate a silicon compound gas in the plasma discharge. A high-efficiency emitter structure is formed on the first surface of the silicon substrate. A back surface passivated structure is formed on the second surface of the silicon substrate. The back surface passivated structure includes a stack of dielectric layers having an inner layer including SiO₂ with a thickness not greater than about 200 Å deposited on the second surface of the silicon substrate and an outer layer including SiNₓ having a thickness not greater than about 200 Å deposited on the inner layer.

In another aspect, the present invention provides a solar cell. The solar cell includes a silicon substrate having a first surface and an opposing second surface. A high-efficiency emitter structure is formed on the first surface. A back surface passivated structure is formed on the second surface.

### BRIEF DESCRIPTION OF THE DRAWINGS

FIG. 1 is schematic view of an exemplary solar cell.

### DETAILED DESCRIPTION OF THE INVENTION

The present invention provides a method for fabricating a silicon solar cell including a dielectric stack layer structure including SiO₂/SiNₓ to produce a back surface passivated (BSP) structure. A front side emitter may be formed by a compositionally graded a-Si:H, such as described in U.S. patent application Ser. No. 11/263,159 entitled Compositionally-Graded Photovoltaic Device and Fabrication Method, filed on Oct. 31, 2005, the disclosure of which is incorporated herein by reference, or any suitable high-efficiency emitter structure that is expected to provide high power conversion efficiency. In order to produce a more efficient crystalline silicon solar cell using aspects of the present invention, the surface recombination velocity may be decreased and the internal optical reflection at the rear surface may be increased. Such goals are realized by optimizing a rear surface to increase optical qualities, such as internal reflection, and/or electrical qualities, such as surface passivation. Silicon solar cells including a dielectric stack layer structure and a high-efficiency front surface emitter structure increase the benefits associated with the dielectric passivation layers, which leads to an increased power conversion efficiency for the solar cell.

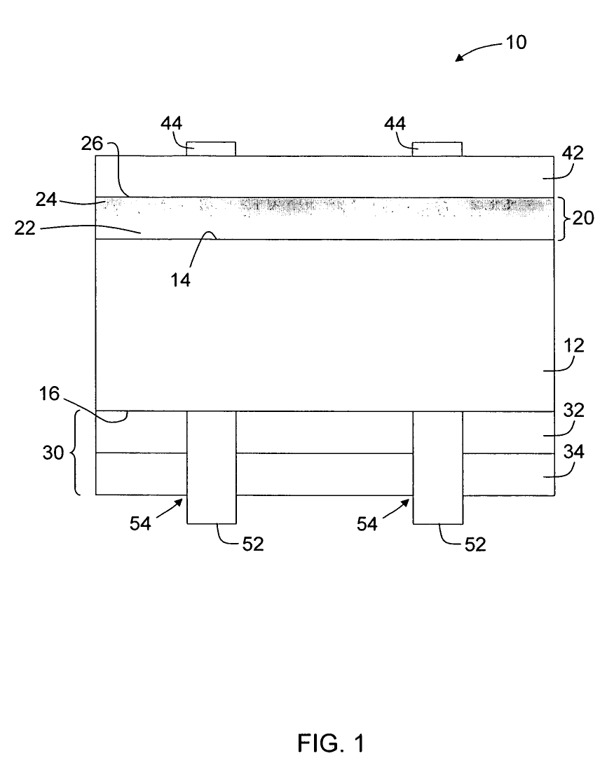

In one embodiment, a method for fabricating a solar cell 10 is provided. Solar cell 10 includes a suitable silicon substrate 12, such as a monocrystalline semiconductor substrate or a multicrystalline semiconductor substrate. As shown in FIG. 1, silicon substrate 12 includes a first or front surface 14 and an opposing second or back surface 16. In one embodiment, front surface 14 and/or back surface 16 is textured using a suitable surface texturing process, such as a wet process using potassium hydroxide (KOH) or a plasma texturing process. It is apparent to those skilled in the art and guided by the teachings herein provided that any suitable texturing process may be used to texture front surface 14 and/or back surface 16.

Silicon substrate 12 is positioned within a plasma reaction chamber, such as a Plasma Enhanced Chemical Vapor Deposition (PECVD) apparatus (not shown). The plasma reaction chamber is evacuated by removing atmospheric gases though a vacuum pump. In this embodiment, H₂ is introduced into the chamber at a flow rate of about 50 sccm to about 500 sccm. A constant processing pressure of about 200 mTorr to about 800 mTorr is maintained within the plasma reaction chamber, such as by using a throttle valve. An alternating frequency input power having a power density of about 3 mW/cm² to about 50 mW/cm² is used to ignite and maintain the plasma. The applied input power has a frequency of about 100 kHz to about 2.45 GHz. Within the plasma reaction chamber, silicon substrate 12 is heated to a temperature of about 120° C. to about 240° C.

A compositionally graded layer structure is formed by introducing SiH₄ into the plasma process chamber at the end of an optional hydrogen plasma preparation step. The SiH₄ is introduced into the plasma process chamber at a flow rate of about 10 sccm to about 60 sccm to initiate a deposition of the compositionally graded layer structure. Because no dopant precursors are included in the plasma, initially the composition of the compositionally graded layer structure is intrinsic (undoped), thus serving to passivate front surface 14 of silicon substrate 12. As the deposition progresses, a dopant precursor is subsequently added to the plasma mixture. Suitable dopant precursors include, without limitation, B₂H₆ and PH₃. The dopant precursors may be in pure form or diluted with a carrier such as argon, hydrogen or helium. The flow rate of the dopant precursor is increased over the course of the deposition process to form a doping concentration gradient. The dopant concentration is substantially zero at the interface with substrate 14, regardless of the particular dopant profile. Thus, an intrinsic region 22 is present at the interface, serving to minimize recombination of the charge carriers. At the conclusion of the deposition process, the concentration of dopant precursor in the plasma is such that substantially doped amorphous semiconductor properties are achieved. Thus, an opposing upper region 24 of graded layer 20 is substantially conductive. The specific dopant concentration in upper region 24 will depend on the particular requirements for the semiconductor device. The thickness of compositionally graded layer 20 will also depend on various factors, such as the type of dopant employed; the conductivity type of the substrate; the grading profile; the dopant concentration in upper region 24; and the optical band gap of layer 20. In one embodiment, a thickness of graded layer 20 is less than or equal to about 250 Å. In a particular embodiment, graded layer 20 has a thickness of about 30 Å to about 180 Å.

A back surface passivated structure 30 is formed on back surface 16 of silicon substrate 12. In one embodiment, BSP structure 30 includes a stack of dielectric layers, as shown in FIG. 1. BSP structure 30 includes a first or inner layer 32 including silicon dioxide (SiO₂) and a second or outer layer 34 including silicon nitride (SiNₓ) formed on and/or bonded to inner layer 32 to form BSP structure 30. With silicon substrate 12 positioned within the plasma reaction chamber, a thin silicon dioxide inner layer 32 having a thickness of not greater than about 200 Å is deposited onto back surface 16. Silicon nitride outer layer 34 having a thickness of not greater than about 200 Å is deposited onto silicon dioxide layer 32. Inner layer 32 and/or outer layer 34 are deposited at low temperatures without breaking the vacuum inside the plasma reaction chamber using SiH₄ and/or NH₃ gases diluted by H₂. Alternatively, inner surface 32 and/or outer surface 34 may be deposited using a suitable process known to those skilled in the art and guided by the teachings herein provided.

The dielectric stack including silicon dioxide inner layer 32 and silicon nitride outer layer 34 provides an effective back surface passivated structure for solar cell 10. The dielectric stack meets the demands of a suitable rear surface scheme including, without limitation, a high internal reflectance for good light trapping and a very good rear surface passivation under operating conditions to achieve high open-circuit voltage (V_{oc}) and J_{sc} values. Further, in one embodiment, internal reflectance is maximized to enable good light trapping characteristics as well as a textured front surface. In conventional solar cells using evaporated aluminum, the reflectance varies between about 50% and about 80%. Thus, the low reflectivity of the evaporated Al does not provide the required light trapping. Conversely, the dielectric stack of this embodiment, including silicon dioxide inner layer 32 and silicon nitride outer layer 34, is expected to provide a high reflectance, which allows for good light trapping in solar cell 10. In addition to the optical properties described above, BSP structure 30 facilitates achieving low recombination velocity values due to the passivation characteristics of the dielectric stack.

As shown in FIG. 1, solar cell 10 further includes at least one transparent conducting film 42 formed or deposited onto emitter layer 20. In one embodiment, a transparent conducting film 42, such as an ITO (Indium Tin Oxide) conducting film, is deposited onto outer surface 26 of emitter layer 20 in order to transport photo-generated charge carriers and minimize reflection. In this embodiment, conducting film 42 is applied to emitter layer 20 using a sputtering deposition process. In alternative embodiments, any suitable process known to those skilled in the art and guided by the teachings herein provided may be used to apply conducting film 42 to emitter layer 20. In this embodiment, metal contacts 44 are formed on conducting film 42 using a silver screen printing process. Metal contacts 44 are utilized to collect and/or transmit the photo-generated current within solar cell 10 to an external load, for example.

As shown in FIG. 1, solar cell 10 further includes at least one metal electrode 52 formed or deposited through BSP structure 30. In one embodiment, a photoresist (not shown) is used to delineate the contact pattern on BSP structure 30. In this embodiment, the photoresist is spin-coated onto outer layer 34. BSP structure 30 is selectively etched and at least one metal contact 52 is positioned within void 54 formed through outer layer 34 and inner layer 32. Metal contacts 52 are deposited within void 54 using a suitable process, such as a sputtering process or an evaporation process. The photoresist is then removed from outer layer 34. Alternatively, metal contact 52 is formed through BSP structure 30 using a screen-printing process to collect and/or transmit the current generated within solar cell 10 to the exterior load. During the screen-printing process, a suitable low temperature (LT) curable silver paste is used. Suitable low temperature curable silver pastes have a curing temperature less than about 200° C.

Aspects of the present invention provide a method for fabricating a solar cell using a PECVD apparatus with depositions at low temperature. Low temperature deposition facilitates the reduction of the thermal budget associated with conventional high temperature diffused cells. Additionally, long-term performance degradation is decreased for low temperature solar cells, thus, providing stable output over longer time periods than conventional solar cells. The SiO₂/SiNₓBSP structure facilitates achieving an improved surface passivation to overcome the disadvantages of high recombination velocity obtained in conventional devices using aluminum. Further, the BSP structure facilitates processing large area solar cell wafers, thereby increasing the power output.

While the invention has been described in terms of various specific embodiments, those skilled in the art will recognize that the invention can be practiced with modification within the spirit and scope of the claims.

What is claimed is:

1. A method for fabricating a solar cell, said method comprising:
positioning a silicon substrate having a front surface and an opposing back surface in a plasma reaction chamber;
forming a high-efficiency emitter structure on the first surface of the silicon substrate; and
forming a back surface passivated structure on the second surface of the silicon substrate.

2. A method in accordance with claim 1 further comprising forming a first conductive electrode on the emitter structure and forming a second conductive electrode through the back surface passivated structure.

3. A method in accordance with claim 2 wherein forming a first conductive electrode on the emitter structure further comprises:
depositing a transparent conducting film on an outer surface of the emitter structure; and
forming at least one metal contact on the transparent conducting film.

4. A method in accordance with claim 2 wherein forming a second conductive electrode on the back surface passivated structure further comprises:
spin coating a photoresist on a surface of the back surface passivated structure;
selectively delineating the photoresist;
etching through selective segments of the back surface passivated structure surface;
depositing at least one metal contact through the back surface passivated structure surface using one of a sputtering process and an evaporation process; and
removing the photoresist from the back surface passivated structure surface.

5. A method in accordance with claim 1 further comprising introducing H₂ into the plasma reaction chamber at a flow rate of about 50 sccm to about 500 sccm.

6. A method in accordance with claim 1 further comprising generating a plasma discharge within the plasma reaction chamber to dissociate a silicon compound gas in the plasma.

7. A method in accordance with claim 1 wherein forming a back surface passivated structure on the back surface of the silicon substrate further comprises forming a stack of dielectric layers including an inner layer comprising SiO₂ having a thickness not greater than about 200 Å and an outer layer comprising SiNₓ having a thickness not greater than about 200 Å.

8. A method in accordance with claim 7 wherein forming a back surface passivated structure on the second surface of the silicon substrate further comprises depositing each of the SiNₓ layer and the SiO₂ layer at a low temperature without breaking the vacuum inside the plasma reaction chamber using a combination of SiH₄ and NH₃ gases diluted by H₂.

9. A method in accordance with claim 1 wherein forming an emitter layer further comprises depositing a compositionally graded layer on the first surface, said method comprising:
introducing SiH₄ into the plasma reaction chamber at a flow rate of about 10 sccm to about 60 sccm to initiate the deposition of the compositionally graded layer;
passivating the first surface of the silicon substrate;
adding a dopant precursor to the plasma mixture wherein the dopant precursor comprises one of B₂H₆ and PH₃; and
increasing a flow rate of the dopant precursor during the deposition of the compositionally graded layer to form a dopant concentration gradient through the compositionally graded layer.

10. A method in accordance with claim 9 further comprising diluting the dopant precursor with a carrier including one of argon, hydrogen and helium.

11. A method for fabricating a solar cell, said method comprising:
positioning a silicon substrate in a plasma reaction chamber;
heating the silicon substrate to a temperature of about 120° C. to about 240° C.;
generating a plasma discharge within the plasma reaction chamber to dissociate a silicon compound gas in the plasma discharge;
forming a high-efficiency emitter structure on the first surface of the silicon substrate; and
forming a back surface passivated structure on the second surface of the silicon substrate, the back surface passivated structure comprising a stack of dielectric layers including an inner layer comprising SiO₂ having a thickness not greater than about 200 Å deposited on the second surface of the silicon substrate and an outer layer comprising SiNₓ having a thickness not greater than about 200 Å deposited on the inner layer.

12. A method in accordance with claim 11 wherein forming a back surface passivated structure on the second surface of the silicon substrate further comprises depositing each of the outer layer and the inner layer at a low temperature without breaking the vacuum inside the plasma reaction chamber using a combination of SiH₄ and NH₃ gases diluted by H₂.

13. A method in accordance with claim 11 wherein forming a high-efficiency emitter structure on the first surface of the silicon substrate comprises forming a compositionally graded layer structure, said method further comprising:
introducing SiH₄ into the process chamber at a flow rate of about 10 sccm to about 60 sccm to initiate a deposition of the compositionally graded layer structure;
passivating the first surface of the silicon substrate;
adding a dopant precursor to the plasma mixture wherein the dopant precursor comprises one of B₂H₆ and PH₃; and
increasing the flow rate of the precursor during the deposition of the compositionally graded layer structure to form a doping concentration gradient through the compositionally graded layer structure.

14. A solar cell comprising:
a silicon substrate having a first surface and an opposing second surface;
a high-efficiency emitter structure formed on said first surface; and
a back surface passivated structure formed on said second surface.

15. A solar cell in accordance with claim 14 wherein said high-efficiency emitter structure comprises a compositionally graded layer structure having a doping concentration gradient through said compositionally graded layer structure.

16. A solar cell in accordance with claim 15 wherein an inner portion of said compositionally graded layer structure is undoped and configured to passivate the first surface of the silicon substrate.

17. A solar cell in accordance with claim 15 wherein said compositionally graded layer structure has a thickness not greater than about 250 Å.

18. A solar cell in accordance with claim 14 wherein said silicon substrate further comprises one of a monocrystalline silicon substrate and a multicrystalline silicon substrate.

19. A solar cell in accordance with claim 14 wherein said back surface passivated structure comprises:
a silicon dioxide layer having a thickness not greater than about 200 Å deposited on said second surface; and
a silicon nitride layer having a thickness not greater than about 200 Å deposited on said silicon dioxide layer.

20. A solar cell in accordance with claim 19 wherein at least one of the silicon dioxide layer and the silicon nitride layer comprises hydrogen.
